(19) United States
(12) Patent Application Publication
(10) Pub. No.: US 2014/0216541 A1
(43) Pub. Date: Aug. 7, 2014

(54) SILICON SUBSTRATE WITH TEXTURE STRUCTURE AND FORMING METHOD THEREOF

(71) Applicant: Panasonic Corporation, Osaka (JP)

(72) Inventors: Naoshi YAMAGUCHI, Osaka (JP); Hiroshi TANABE, Nara (JP)

(73) Assignee: Panasonic Corporation, Osaka (JP)

(21) Appl. No.: 14/164,262

(22) Filed: Jan. 27, 2014

(30) Foreign Application Priority Data
Feb. 6, 2013 (JP) 2013-021081

(51) Int. Cl. H01L 31/0236; H01L 21/306

(52) U.S. Cl. CPC H01L 31/02366; H01L 21/30604
USPC 136/256; 438/704

(57) ABSTRACT

A silicon substrate includes a texture structure in which quadrangular pyramid-shaped first textures having a (111) plane on slopes are formed on a surface of the silicon substrate having a plane orientation (100) and second textures having etch pits surrounded by three planes of the (100) plane, a (010) plane and a (001) plane are formed on surfaces of the first textures.

### BACKGROUND OF THE INVENTION

1. Field of the Invention

The present invention relates to a substrate having a texture structure used for a solar cell.

2. Description of Related Art

A silicon solar cell (photoelectric conversion device) has a rough shape called textures on a light receiving surface of a silicon substrate to thereby suppress reflection of incident light and prevent light taken into the silicon substrate from leaking to the outside. The formation of textures on the surface of the silicon substrate is generally performed by wet etching using an alkaline solution (solution formed by adding a surface-active agent to a solution of KOH, NaOH or the like).

The textures formed by wet watching generally have quadrangular pyramid-shaped projections. Dissolving reaction of silicon in the alkaline solution is represented by the following formulas.

Si+4OH→Si(OH)₄+4e′. . . (A)

2H₂O+2e⁻→2OH+H₂↑. . . (B)

An etching rate in chemical reactions of chemical formulas (A) and (B) differs according to a plane orientation, and it is known that an etching rate ratio of a (100) plane with respect to a (111) plane is 200 or more and the (111) plane is hardly etched selectively.

Accordingly, to fabricate quadrangular pyramid-shaped textures as shown in FIG. 2, the above property is utilized. A silicon substrate with a plane orientation (100) has a substrate surface of a (100) plane 1 of silicon before forming textures. When an impurity such as a reaction product or a surface-active agent in the solution adheres to the substrate surface, the portions function as a self-alignment mask 2 and the (100) plane 1 of silicon is etched. As a (111) plane 3 of silicon is not etched, therefore, quadrangular pyramid-shaped textures are formed, in which mask portions are vertexes of quadrangular pyramids and the (111) planes 3 of silicon form slopes of quadrangular pyramids.

When the quadrangular pyramid-shaped textures are formed on the silicon substrate as described above, light incident on the substrate surface is obliquely reflected on the slope of the quadrangular pyramid and scattered, therefore, the light is taken into the substrate efficiently. Accordingly, a property required for the textures is reflectance, and the reflectance is required to be reduced.

Additionally, quadrangular pyramid-shaped textures are bonded in a fixed bonding surface when an upper layer film such as amorphous silicon is deposited. Accordingly, there is also an advantage that electrical loss on the interface can be suppressed to be low.

FIG. 3 is a micrograph of textures formed by wet etching the silicon substrate having the plane orientation (100) by an alkaline solution. The micrograph shows that quadrangular pyramid-shaped textures are actually formed.

In recent years, reflection on textures has been further reduced, and a technique of forming smaller textures on slopes of quadrangular pyramid-shaped textures as described above has been developed. For example, there is known a method in which, after the quadrangular pyramid-shaped textures are formed by the above wet etching, random and fine unevenness are formed on slopes of quadrangular pyramid-shaped textures by plasma dry etching using CF4 or SF6 gas to thereby roughening the surface (for example, refer to JP-A-2007-36170 (Patent Document 1).

On the other hand, there is also proposed a method of etching the surface of the silicon substrate by arranging the silicon substrate in a reaction chamber under atmospheric pressure and introducing gas such as ClF3 into the reaction chamber (refer to JP-A-10-313128 (Patent Document 2)). The method is a dry etching method not using plasma, which is expected as a process with low damage.

### SUMMARY OF THE INVENTION

However, in the technique disclosed in Patent Document 1, the bonding surface is not bonded in a fixed plane orientation in the bonding with respect to the upper layer film such as amorphous silicon deposited on a texture layer though the technique is effective for reducing the reflection. Additionally, ion damage due to plasma also occurs. As a result, the electrical loss occurs on the interface of the bonding surface, which causes a problem that comprehensive power generating efficiency as a solar cell is not expected.

Accordingly, the present invention has been made for solving the related art problems and an object thereof is to provide a silicon substrate with a texture structure and a forming method thereof in which large increase of efficiency can be expected as the comprehensive power-generating efficiency as the solar cell.

When the above problems are solved, a silicon substrate with textures according to the present invention allows a bonding surface to be fixed in the bonding with respect to the upper layer film in addition to further reduction of reflection. Additionally, it is possible to provide a substrate with textures without ion damage due to plasma.

The substrate having textures according to the invention for solving the above problems is a silicon substrate having a plane orientation (100), in which quadrangular pyramid-shaped first textures are formed first by wet etching using the alkaline solution. The (111) plane is formed as slopes according to the chemical reactions represented by the above chemical formulas (A) and (B).

On the slopes, fine textures having etch pits surrounded by three planes of the (100) plane, a (010) plane and a (001) plane are formed as second textures by dry etching using gas including ClF3 and O2 to thereby firm the substrate.

Here, a mechanism in which the silicon substrate having the plane orientation (111) is exposed to mixed gas including ClF3 and O2 to perform dry etching without generating plasma will be described. The mechanism can be explained as the following chemical reaction as a result of study by the writer et al.

3Si+4ClF₃→3SiF₄↑+2Cl₂↑ . . . (C)

Si+O₂→SiO₂ . . . (D)

FIG. 4 is a view of textures obtained by etching the silicon substrate of the plane orientation (111) using mixed gas including ClF3 and O2.

When the silicon substrate is exposed to the ClF3 gas, ClF3 is decomposed and silicon reacts to be SiF4 as expressed by the chemical formula (C). As SiF4 is a gas, it breaks away from the silicon substrate. On the other hand, as O2 exists in the mixed gas, the etching proceeds through the reaction of the chemical formula (C) and SiO2 is microscopically formed due to the reaction of the chemical formula (D). As SiO2 does not react to ClF3 and is not etched, the microscopically-formed SiO2 functions as a self-alignment mask 4 and etching along the plane orientation is performed by using the self-alignment mask 4 as starting points. When the plane exposed to the mixed gas is the (111) plane, the (100) plane 5 of silicon, the (010) plane 6 of silicon and the (001) plane 7 of silicon are exposed, and the textures having etch pits surrounded by these three planes are formed.

FIG. 5 is a micrograph of textures obtained when the silicon substrate having the plane orientation (111) has been actually dry-etched by mixed gas including ClF3 and O2. The drawing shows that textures having etch pits surrounded by the (100) plane, the (010) plane and the (001) plane are formed.

The mixed gas used for the etching is the mixed gas including ClF3 and O2 using N2 gas as a dilution gas, which can control the size of textures by the ratio of concentrations as described above. It is preferable that the ratio of concentrations of the mixed gas is approximately 20% or less in the concentration of ClF3 and 70% or less in the concentration of O2 though it is difficult to be uniformly mentioned when considering various conditions such as a reaction container, environmental temperature and pressure.

FIG. 1A and 1B show a silicon substrate with textures and a manufacturing method thereof according to the invention. As a manufacturing method of the silicon substrate with textures, a step of wet etching the silicon substrate having the plane orientation (100) by an alkaline solution and a step of dry etching the silicon substrate having the (111) plane on the surface by using mixed gas including ClF3 and O2 are combined to thereby manufacture the silicon substrate with textures.

First, as shown in FIG. 1A, the silicon substrate having the plane orientation (100) is wet etched by using the alkaline solution to thereby form quadrangular pyramid-shaped first textures 8. Slopes of the quadrangular pyramid-shaped first textures 8 have the (111) plane 3 of silicon.

After that, dry etching is performed by using mixed gas including ClF3 and O2. Then, second fine textures 9 having etch pits surrounded by three planes of the (100) plane 5 of silicon, the (010) plane 6 of silicon and the (001) plane 7 of silicon can be formed on the slopes of the quadrangular pyramid-shaped first textures 8 as the (111) plane 3 of silicon as shown in FIG. 1B.

As is obvious, the second fine textures 9 having etch pits are formed by the same mechanism as in the case of dry etching the silicon substrate having the plane orientation (111) by using mixed gas including ClF3 and O2 as shown by the view of forming textures in FIG. 4.

The substrate with textures has plural advantages.

First, as the slopes of the quadrangular pyramids, are not merely roughened, and the (100) plane, the (010) plane and the (001) plane are exposed on the slopes, therefore, an upper layer film such as amorphous silicon can be bonded with respect to particular plane orientations which are the (100) plane, the (010) plane and the (001) plane. The electrical loss can be suppressed as compared with the bonding to the merely roughened surface, which can increase the efficiency.

Secondly, when textures are arranged based on geometric arrangement, the bonding area with respect to the upper layer film can be increased as compared with the common quadrangular pyramid-shaped texture substrate.

Thirdly, when the surfaces of quadrangular pyramid-shaped textures are roughened by using plasma etching as cited in Patent Document 1, ion damage due to plasma inevitably occurs. However, the etching without generating plasma is performed in the present invention, therefore, low damage can be expected and reduction of efficiency is thus suppressed.

As described above, large increase of efficiency can be expected as comprehensive power-generating efficiency as the solar cell by using the texture substrate according to the present invention.

### BRIEF DESCRIPTION OF THE DRAWINGS

FIGS. 1A and 1B are views showing a substrate with textures according to the present invention;

FIG. 2 is a view of forming textures in a case of wet etching a silicon substrate having a plane orientation (100) by using an alkaline solution;

FIG. 3 is a micrograph of quadrangular pyramid-shaped textures obtained by wet etching the silicon substrate having the plane orientation (100) by using the alkaline solution;

FIG. 4 is a view of forming textures in a case of dry etching a silicon substrate having a plane orientation (111) by using mixed gas including ClF3 and O2;

FIG. 5 is a micrograph of textures obtained by dry etching the silicon substrate having the plane orientation (111) by using mixed gas including ClF3 and O2;

FIGS. 6A and 6B are micrographs of textures according to an embodiment of the present invention;

FIG. 7A is a view showing the reflectance of a substrate with textures according to the embodiment of the present invention and FIG. 7B is a view showing the reflectance of a substrate with quadrangular pyramid-shaped textures obtained by wet etching the silicon substrate having the plane orientation (100) by using an alkaline solution;

FIGS. 8A and 8B are views for explaining the surface area of textures according to the present invention;

FIG. 9 is a chart showing a manufacturing flow according to the embodiment of the invention;

FIG. 10 is a view showing a wet etching device according to the embodiment of the present invention: and

FIG. 11 is a view showing a dry etching device according to the embodiment of the present invention.

### DESCRIPTION OF EMBODIMENTS

Hereinafter, an embodiment of the present invention will be explained with reference to the drawings.

### Embodiment

[Substrate with Textures]

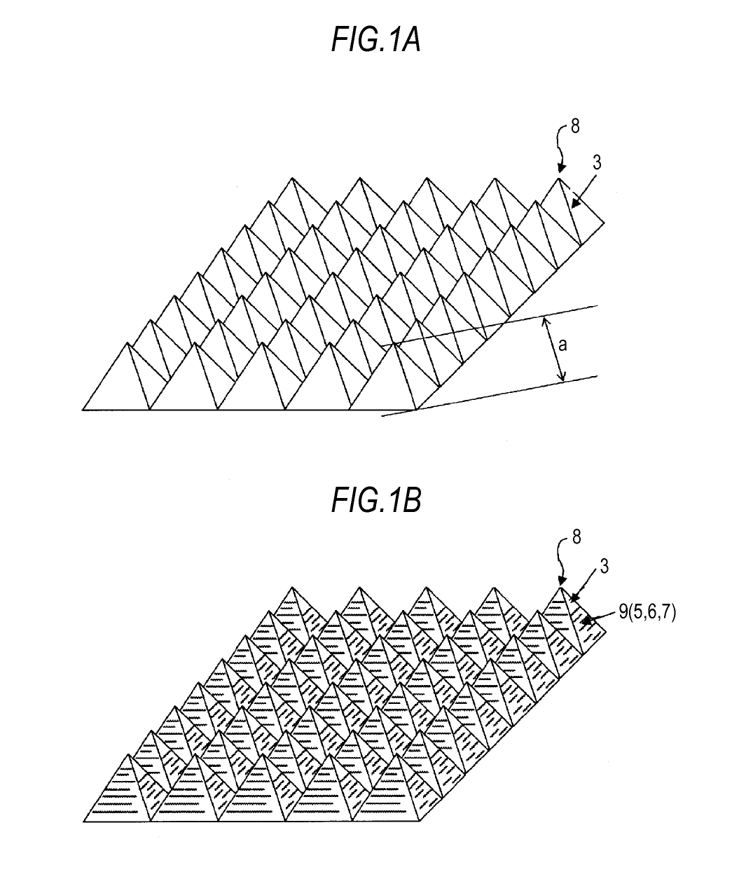

FIG. 3 is a micrograph of quadrangular pyramid-shaped textures obtained by wet etching a silicon substrate having a plane orientation (100) by an alkaline solution. In the present invention, quadrangular pyramid-shaped first textures 8 shown in FIG. 1A are shown.

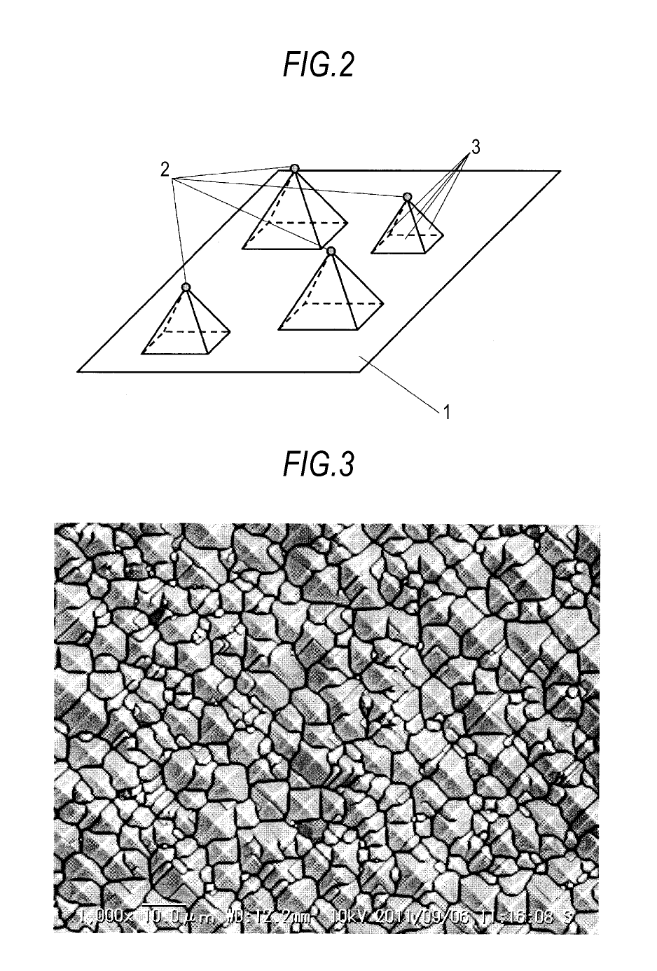

When the size of the quadrangular pyramid-shaped first texture 8 is defined by a length “a” of an oblique side of the quadrangular pyramid-shaped first texture 8 shown in FIG. 1A, the length “a” of the oblique side is approximately 1 μm or more to 20 μm or less, and approximately 10 μm on average as shown by an actual micrograph shown in FIG. 2.

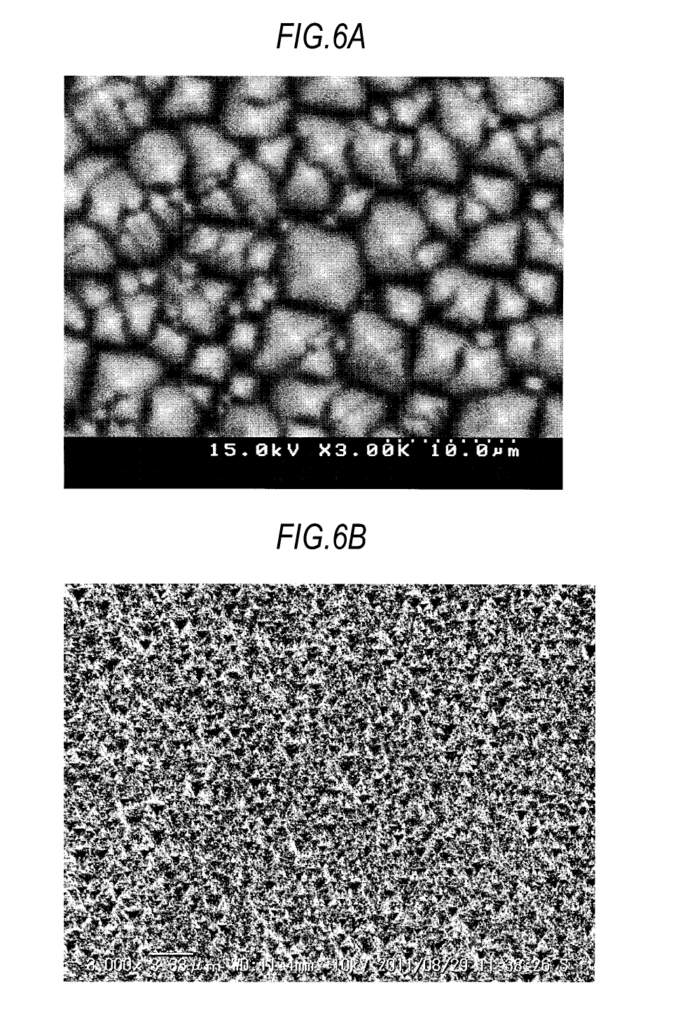

Next, a substrate having the quadrangular pyramid-shaped first textures 8 is etched by using mixed gas including ClF3 and O2. Micrographs of textures in this case are shown in FIGS. 6A and 6B. As shown in FIG. 6B, second fine textures 9 having etch pits surrounded by three planes of a (100) plane 5 of silicon, a (010) plane 6 of silicon and a (001) plane 7 of silicon are formed on the slopes of the quadrangular pyramid-shaped first textures 8 as a (111) plane 3 of silicon.

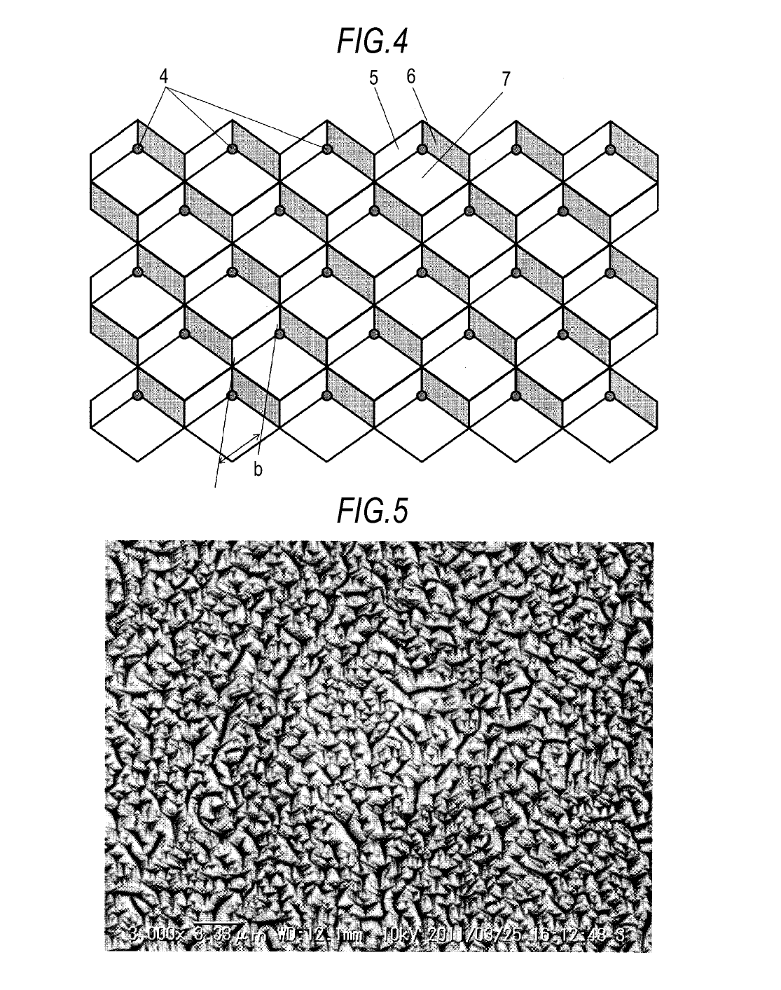

When the size of the second fine textures is defined by a length “b” of an oblique, side of the second fine texture shown in FIG. 4, the length “b” of the oblique side is approximately 0.1 μm or less as shown by an actual micrograph shown in FIG. 5.

As described above, after quadrangular pyramids having the (111) plane on slopes are formed by wet etching the silicon substrate having the (100) plane on the surface using the alkaline solution, the silicon substrate is etched by being exposed to the nixed gas including ClF3, thereby forming the fine textures having the etch pits surrounded by three planes of the (100) plane, the (010) plane and the (001) plane on the slopes of the (111) plane.

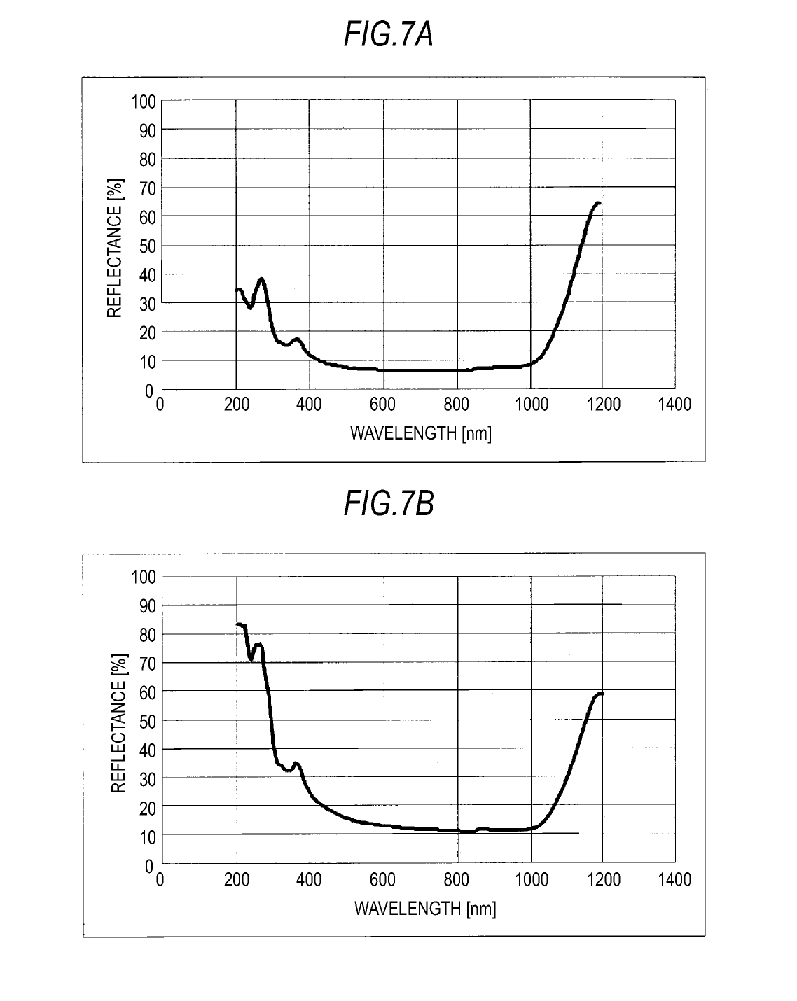

FIG. 7A shows a result of measuring the reflectance of the substrate with textures according to the embodiment of the present invention. FIG. 7B shows a result of measuring the reflectance of the related-art silicon substrate on which only quadrangular pyramid-shaped first textures are formed.

On the whole, the reflectance is lower in the silicon substrate according to the present invention, which indicates that use efficiency of light is higher. Generally, the reflectance of silicon substrates with textures is compared by using a reflectance at a wavelength 840 nm as a representing value in many cases. In this case, the reflectance at the wavelength 840 nm is 11% in the related-art silicon substrate on which only the quadrangular pyramid-shaped first textures are formed shown in FIG. 7B, whereas the reflectance at the wavelength 840 nm is 6.6% in the substrate with textures according to the embodiment of the present invention shown in FIG. 7A, which indicates that the reflectance has been drastically reduced.

In the shape of textures, when a ratio between the length “a” of the oblique side of the quadrangular pyramid-shaped first texture and the length “b” of the oblique side of the fine texture having the etch pit surrounded by three surfaces of the (100) plane, the (010) plane and the (001) plane is approximately 200:1 to 10:1, the advantage of the low reflectance as described above can be obtained.

Additionally, in the case where textures are arranged based on geometric arrangement as the above case, the bonding area with respect to the upper layer film is increased as compared with the common substrate with quadrangular pyramid-shaped textures.

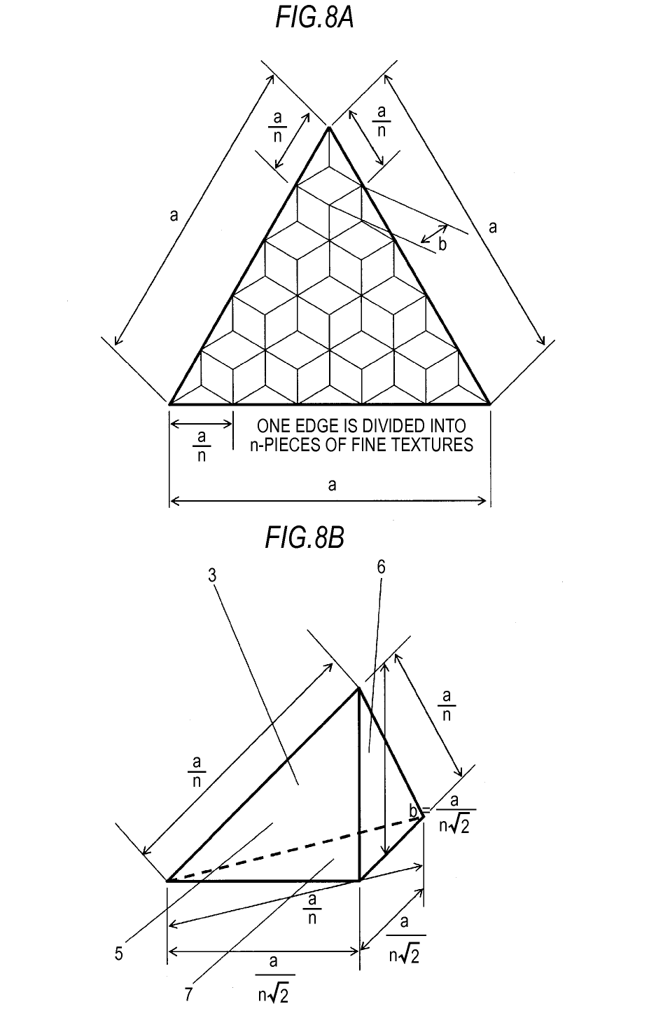

The above will be explained with reference to FIGS. 8A and 8B. FIG. 8A is a view showing a state where fine textures divided into “n” pieces in each side which are surrounded by the (100) plane, the (010) plane and the (001) plane are ideally arranged on the slope of the quadrangular pyramid-shaped texture. When the length of one side is “a”, the slope of the quadrangular pyramid-shaped texture will be an equilateral triangle with a length “a”. A length of a base of the etch pit divided into “n” pieces will be a/n.

FIG. 8B shows one piece taken from the above fine textures which are divided into “n” pieces. A surface of an equilateral triangle surrounded by sides each having a length “a/n” is the slope of the quadrangular pyramid-shaped texture and is equivalent to the (111) plane 3 of silicon. The area of the (111) plane 3 will be 3^{1/2}a²/4n² according to calculation. On the other hand, the fine texture is surrounded by three planes of the (100) plane 5 of silicon, the (010) plane 6 of silicon and the (001) plane 7 of silicon respectively, therefore, the total of these three surfaces will be 3a²/4n² at to geometric calculation.

That is, when fine textures surrounded by three planes of the (100) plane, the (010) plane and the (001) plane are formed on the slopes, the surface area is 3^{1/2} times increased as compared with the case where only the quadrangular pyramid-shaped slopes are formed. The bonding area with respect to the upper layer film in the substrate with textures according to the invention will be 3^{1/2} times increased as comp are d with the substrate with quadrangular pyramid-shaped textures in theory. This feature can also contribute to high efficiency.

[Manufacturing Method of Silicon Substrate with Texture Structure]

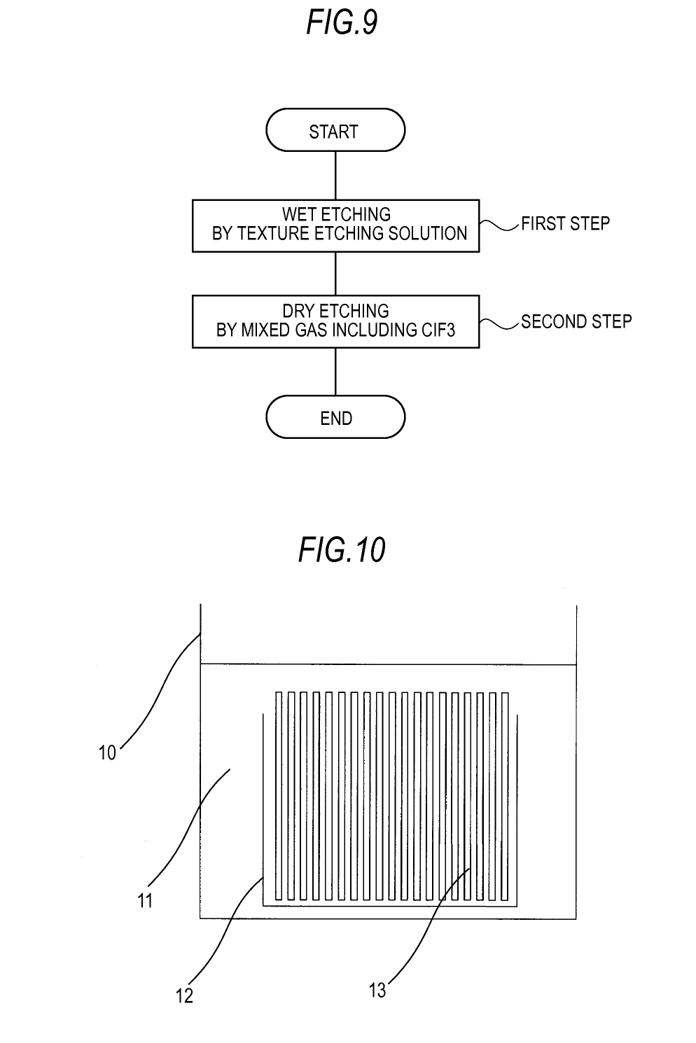

FIG. 9 is a flowchart showing a manufacturing method according to the embodiment of the invention. A silicon substrate having the plane orientation (100) is prepared, and the method includes a step of performing etching by using an etching solution for textures as a first step and a step of performing thy etching using gas including ClF3 gas as a second step.

FIG. 10 shows a wet etching device used in the first step. A cassette 12 on which a silicon substrate 13 is placed is sunk in a solution bath 10 in which a wet etching solution 11 for forming textures is prepared, which is formed by adding a surface-active agent to an aqueous solution such as KOH or NaOH. The etching time is approximately 20 times to 60 times.

As textures on the surface of the silicon substrate formed by wet etching, quadrangular pyramid-shaped textures having the (111) plane on slopes are formed by using the fact that the etching rate ratio of the (100) plane with respect to the (111) plane is 200 or more according to the above-described chemical formulas (A) and (B).

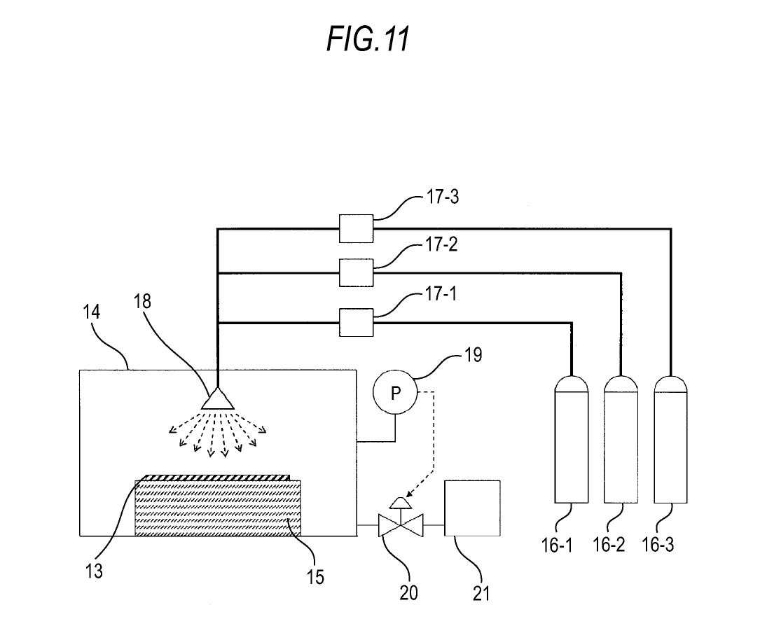

FIG. 11 shows a dry etching device using the ClF3 gas used in the second step.

A stage 15 is provided in a chamber 14. The silicon substrate 13 is placed on the stage 15, and ClF3 gas can be supplied to a gas cylinder 16-1, O2 gas can be supplied to a gas cylinder 16-2 and N2 gas can be supplied to a gas cylinder 16-3 as a dilution gas. The flow rate of these gases is controlled through mass flow controllers 17-1, 17-2 and 17-3 respectively, then, these gases are sprayed on the surface of the silicon substrate 13 from a shower nozzle 18. After that, the gas inside the chamber 15 is exhausted from a blower 21 while the pressure is adjusted to the set pressure by a pressure gauge 19 and a pressure adjustment valve 20.

The substrate with quadrangular pyramid-shaped textures having the (111) plane on the slopes formed in the first step is exposed to the mixed gas including the ClF3 gas by using the device to perform etching processing.

The reaction in the above reaction formulas (C) and (D) is promoted by the dry etching using the ClF3 gas, and the second fine textures having etch pits surrounded by three planes of the (100) plane, the (010) plane and the (001) plane on the (111) plane as the slopes of the quadrangular pyramids formed in the first step.

The concentration of mixed gas including the ClF3 gas depends on various conditions such as a reaction container, environmental temperature, pressure and so on, and it is desirable that the ClF3 gas is 10% or less and the O2 gas is 40% or less with respect to the N2 as the dilution gas. That is because, when applying a concentration higher than the above, the reaction of dry etching using the ClF3 gas is promoted too much and the quadrangular pyramid-shaped first textures formed in the first step are also etched.

When the texture substrate according to the present invention is used, large increase of efficiency can be expected as comprehensive power-generating efficiency as the solar cell.

What is claimed is:

1. A silicon substrate with a texture structure, the silicon substrate comprising:
quadrangular pyramid-shaped first textures having a (111) plane on slopes formed on a surface of the silicon substrate having a plane orientation (100); and
second textures having etch pits including a (100) plane, a (010) plane and a (001) plane formed on surfaces of the first textures.

2. The silicon substrate with the texture structure according to claim 1,
wherein a length of an oblique side of each of the second textures is smaller than a length of an oblique side of each of the first textures.

3. The silicon substrate with the texture structure according to claim 2,
wherein a ratio between the length of the oblique side of each of the first textures and the length of the oblique side of each of the second textures is between 200:1 to 10:1.

4. The silicon substrate with the texture structure according to claim 2,
wherein the length of the oblique side of each of the first textures is 1 μm or more to 15 μm or less; and
the second texture is a triangular-pyramid shaped texture and the length of the oblique side of the triangular-pyramid shaped texture is 0.1 82 m or less.

5. A forming method of a silicon substrate with textures formed on the surface, comprising the steps of:
forming first textures by wet etching the silicon substrate using an alkaline solution; and
forming second textures by non-plasma dry etching the e silicon substrate using gas including chlorine trifluoride.

6. The forming method of the silicon substrate according to claim 5,
wherein the gas including chlorine trifluoride includes nitrogen gas and oxygen gas, which is mixed gas in which the concentration of chlorine trifluoride is 10% or less and the concentration of oxygen is 40% or less.

7. The silicon substrate with the texture structure according to claim 1,
wherein a ratio between the length of the oblique side of each of the first textures and the length of the oblique side of each of the second textures is between 200:1 to 10:1.

8. The silicon substrate with the texture structure according to claim 1,
wherein the length of the oblique side of each of the first textures is 1 μm or more to 15 μm or less; and
the second texture is a triangular-pyramid shaped texture and the length of an oblique side of the triangular-pyramid shaped texture is 0.1 μm or less.
